(19) United States
(12) Patent Application Publication
(10) Pub. No.: US 2017/0322600 A1
(43) Pub. Date: Nov. 9, 2017

(54) COMPOSITIONS HAVING A MATRIX AND A HYDRATED SALT OF AN ACID AND A GROUP I OR II ELMENT OF THE PERIODIC TABLE DISPERSED THEREIN, AND ELECTRONIC DEVICES ASSEMBLED THEREWITH

(71) Applicants: Henkel IP & Holding GmbH, Duesseldorf (DE); Henkel AG & Co. KGaA, Duesseldorf (DE)

(72) Inventors: My Nhu Nguyen, Poway, CA (US); Qiaohong Huang, Trabuco Canyon, CA (US); Uta Sundermeier, Leichlingen (DE)

(21) Appl. No.: 15/588,212

(22) Filed: May 5, 2017

Related U.S. Application Data
(63) Continuation of application No. PCT/US2015/058788, filed on Nov. 3, 2015.
(60) Provisional application No. 62/074,314, filed on Nov. 3, 2014.

(51) Int. Cl. G06F 1/16; H01L 23/552; H01L 23/373; H01M 10/623; H01M 10/613; C09K 5/14; C09D 5/26; C09D 4/00; H01M 10/659; G06F 1/20; H01L 23/367

(52) U.S. Cl. CPC G06F 1/1656; G06F 1/203; H01L 23/552; H01L 23/3737; H01L 23/3735; H01L 23/3675; H01M 10/613; C09K 5/14; C09D 5/26; C09D 4/00; H01M 10/659; H01M 10/623; H01M 2220/30

(57) ABSTRACT

Provided herein are compositions made from a matrix and a hydrated salt of an acid and a Group I or II element of the Periodic Table, and electronic devices assembled therewith.

### BACKGROUND

### Field

Provided herein are compositions made from a matrix and a hydrated salt of a carboxylic or phosphoric acid and a Group I or II element of the Periodic Table, and electronic devices assembled therewith.

### Brief Description of Related Technology

Thermal management materials are well known for dissipating heat generated by the circuitry and fans placed at strategic locations within an electronic device also draw heat away from the circuitry, or thermal module. The excess heat is diverted away from the semiconductor package to a heat sink or the thermal module with a thermal interface material (“TIM”), oftentimes disposed between the semiconductor package and the heat sink or thermal module.

However, these strategies to manage generated heat have created new problems, as the hot air is directed away from the immediate environment of the semiconductor package toward the interior of the housing of the device.

More specifically, in a conventional laptop or notebook computer (shown in FIG. 2), a housing exists under which are the components below the keyboard (shown in FIG. 3). The components include a heat sink, a heat pipe (disposed above a CPU chip), a fan, a slot for the PCMIA card, a hard drive, a battery, and a bay for a DVD drive. The hard drive is disposed under the left palm rest and the battery under the right. Oftentimes, the hard drive operates at high temperatures, resulting in uncomfortable palm rest touch temperatures, despite the use of cooling components to dissipate this heat. This may lead to end user consumer discomfort due to hot temperatures attained at certain portions of the exterior of the device when the devices are used.

One solution to mute the high in use temperatures observed by the end user at the palm rest position, for instance, is to use natural graphite heat spreaders disposed at strategic locations. These heat spreaders are reported to distribute heat evenly while providing thermal insulation through the thickness of the material. One such graphite material is available commercially as eGraf® SpreaderShield™ from GrafTech Inc., Cleveland, Ohio. [See M. Smalc et al., “Thermal Performance Of Natural Graphite Heat Spreaders”, Proc. IPACK2005, Interpack 2005-73073 (July, 2005); see also U.S. Pat. No. 6,482,520.]

Alternative thermal management solutions are desirable and would be advantageous, as there is a growing need in the marketplace for ways in which to manage the heat generated by such semiconductor packages used in electronic devices so that end user consumers do not feel discomfort due to the generated heat when they are used. Balanced against this need is the recognition that designers of semiconductor chips will continue to reduce the size and geometry of the semiconductor chips and semiconductor packages but increase their computing capacity. The competing interests of size reduction and increased computing power make the electronic devices appealing for the consumer, but in so doing causes the semiconductor chips and semiconductor packages to continue to operate at elevated temperature conditions, and indeed increasing elevated temperature conditions. Accordingly, it would be advantageous to satisfy this growing need with alternative technologies to encourage the design and development of even more powerful consumer electronic devices, which have reduced “skin temperature” and as such are not hot to the touch in operation.

### SUMMARY

Provided herein is a composition comprising (a) a matrix; and (b) a hydrated salt of an acid and a Group I or II element of the Periodic Table. The composition is capable of absorbing heat. As such, in use it may be disposed onto at least a portion of a surface of a heat spreading device constructed from conductive materials, such as metal or metal-coated polymeric substrate, or graphite or metal-Substitute coated graphite, examples of which include Cu, Al, and graphite, and Cu- or Al-coated graphite.

The compositions have a temperature range within which phase change from solid to liquid occurs of about 40° C. to 80° C. The inventive compositions are suitable for producing films having a substantially uniform thickness coated on a substrate.

The matrix of the composition may be a resin based one, such as a pressure sensitive adhesive (“PSA”), as those adhesives are commonly referred to, or an acrylic emulsion. In addition, the matrix may be the cured product of a RedOx curable composition, such as one including a (meth)acrylate and/or a maleimide-, an itaconimide- or a nadimide-containing compound.

Where the matrix is a PSA, the composition may be disposed onto at least a portion of a surface of a heat spreading device to provide both EMI shielding and to enhance thermal performance of such device.

The composition may also function as a thermal absorber film for use in a transfer tape format so that the composition may be applied to any location on the device that requires cooling, such as on the interior of an EMI shield. Desirably, in such use, the encapsulated phase change material is coated on at least a portion of the surface thereof with a metal coating.

Where the matrix is an acrylic emulsion, while the composition may likewise be so dispersed, the carrier liquid of the emulsion is evaporated prior to placing the composition under operating conditions.

The composition may be disposed onto a substrate or between two substrates. The substrate(s) may serve as a support or may serve as a heat spreader, in which case the support may be constructed from a conductive material which is a metal or a metal-coated polymeric substrate, or graphite or a metal-coated graphite.

The composition may be used with an article, such as a power source like a battery module to dissipate heat generated by the power source during operation. That operating temperature may be as high as about 40° C. In this embodiment, a housing comprising at least one substrate having an interior surface and an exterior surface is provided over and/or about the article and on an interior facing surface thereof, and a composition comprising a plurality of encapsulated phase change material particles dispersed within a matrix disposed upon a substrate, which as noted above may serve as a support or provide thermal conductivity to aid in spreading the generated heat, is disposed on at least a portion of the interior surface of the at least one substrate. In one aspect the encapsulated phase change material particles may have a layer of a conductive material disposed on at least a portion of the surface of the particles. The conductive coating should be metallic such as Ag, Cu or Ni so as to provide an EMI shielding effect.

In an embodiment for use in a consumer electronic article of manufacture, a housing is provided which comprises at least one substrate having an interior surface and an exterior surface; a composition is provided which comprises a plurality of encapsulated phase change material particles dispersed within a matrix disposed upon a substrate, which as noted above may serve as a support or provide thermal conductivity to aid in spreading the generated heat, which layer is disposed on at least a portion of the interior surface of the at least one substrate; and at least one semiconductor package is provided which comprises an assembly comprising at least one of
I.
   a semiconductor chip;
   a heat spreader; and
   a thermal interface material therebetween (also known as a TIM1 application)
II.
   a heat spreader;
   a heat sink; and
   a thermal interface material therebetween (also known as a TIM2 application).

Also, provided herein is a method of manufacturing such a consumer electronic device.

### BRIEF DESCRIPTION OF THE FIGURES

FIG. 1 depicts a cut away view of a circuit board on which is disposed a plurality of semiconductor packages and circuitry, together with electronic materials ordinarily used in the assembly of the packages themselves and the assembly of the packages onto the board. Reference numbers 1-18 refer to some electronic materials used in the packaging and assembly of semiconductors and printed circuit boards.

FIG. 2 depicts a laptop personal computer in the open position.

FIG. 3 depicts a top view of the contents of the laptop personal computer, beneath the keyboard and palm rests thereof.

FIG. 4 depicts a general schematic diagram of an electronic device.

FIG. 5 depicts a plan view of the locations for skin temperature measurements in a tablet.

FIG. 6A shows a representation of layers of the inventive composition, where a composition including a matrix with in which is dispersed compositions having a matrix and a hydrated salt of an acid and a Group I or II element of the Periodic Table dispersed therein, and electronic devices assembled therewith (61) is placed in contact with a conductive support (62).

FIG. 6(B) shows a representation of layers of the inventive composition where a composition including a matrix with in which is dispersed compositions having a matrix and a hydrated salt of an acid and a Group I or II element of the Periodic Table dispersed therein, and electronic devices assembled therewith (63) is placed in contact with a conductive support (64), to form an EMI shielding thermal absorbing film.

FIG. 7 depicts a top view within the housing of a tablet of a power module under which the inventive composition (not shown) is disposed.

### DETAILED DESCRIPTION

As noted above, provided herein is a composition comprising: (a) a matrix; and (b) a hydrated salt of an acid and a Group I or II element of the Periodic Table.

The composition may be disposed onto a substrate or between two substrates. The substrate(s) may serve as a support or may serve as a heat spreader, in which case the support may be constructed from a conductive material which is metal or metal-coated polymeric substrate, or graphite or a metal-coated graphite.

The composition comprises a matrix (such as a PSA, an acrylic emulsion or a radically curable component, such as a (meth)acrylate and/or a maleimide-, an itaconimide- or a nadimide-containing compound), in which is dispersed a hydrated salt of an acid and a Group I or II element of the Periodic Table. Optionally, the composition may also include thermally insulative elements. In one embodiment, a metallic or graphite substrate may be used as a support on which the composition is disposed. In this way the metallic or graphite substrate may acts as a heat spreader to further dissipate heat.

The composition—e.g., the PSA in which is dispersed a hydrated salt of an acid and a Group I or II element of the Periodic Table—may be coated on a heat spreading device, such as a metal like Cu or Al, graphite, or a metal-coated graphite—to enhance thermal performance of such devices.

The composition may be coated on a heat spreading device to also provide EMI shielding as well as to enhance thermal performance of such devices.

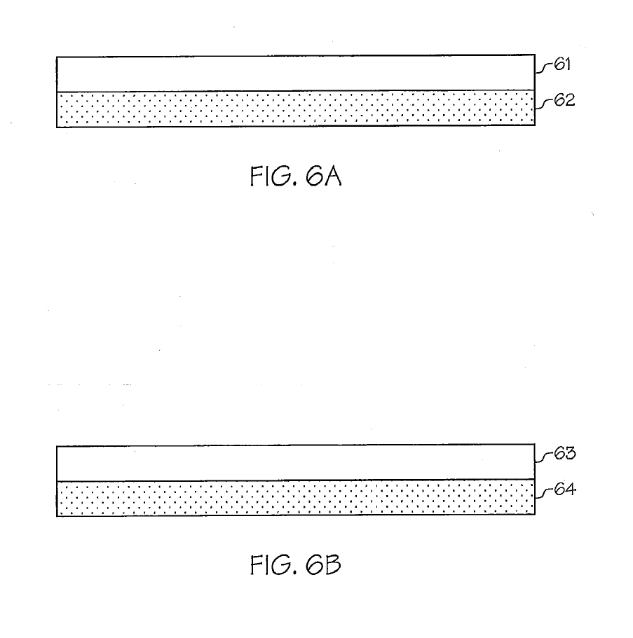

In the form of a transfer tape, the composition as a thermal absorber film may be applied to any location that requires cooling, such as inside the EMI shield. See e.g. FIGS. 6A or 6B.

The composition may be used with an article, such as a power source like a battery module to dissipate heat generated by the power source during operation. That operating temperature may be as high as about 40° C. In this embodiment, a housing comprising at least one substrate having an interior surface and an exterior surface is provided over and/or about the article and on an interior facing surface thereof a composition comprising a matrix and a hydrated salt of an acid and a Group I or II element of the Periodic Table disposed upon a substrate, which as noted above may serve as a support or provide thermal conductivity to aid in spreading the generated heat, is disposed on at least a portion of the interior surface of the at least one substrate.

In an embodiment for use in a consumer electronic article of manufacture, a housing is provided which comprises at least one substrate having an interior surface and an exterior surface; a composition is provided which comprises a matrix and a hydrated salt of an acid and a Group I or II element of the Periodic Table disposed upon a substrate, which as noted above may serve as a support or provide thermal conductivity to aid in spreading the generated heat, which layer is disposed on at least a portion of the interior surface of the at least one substrate; and at least one semiconductor package is provided which comprises an assembly comprising at least one of
I.
   a semiconductor chip;
   a heat spreader; and
   a thermal interface material therebetween (also known as a TIM1 application)
II.
   a heat spreader;
   a heat sink; and
   a thermal interface material therebetween (also known as a TIM2 application).

The composition may be used in the assembly of a consumer electronic article of manufacture. This article of manufacture (or “device”) may be selected from notebook personal computers, tablet personal computers or handheld devices, for instance, music players, video players, still image players, game players, other media players, music recorders, video recorders, cameras, other media recorders, radios, medical equipment, domestic appliances, transportation vehicle instruments, musical instruments, calculators, cellular telephones, other wireless communication devices, personal digital assistants, remote controls, pagers, monitors, televisions, stereo equipment, set up boxes, set-top boxes, boom boxes, modems, routers, keyboards, mice, speakers, printers, and combinations thereof.

The device may also include a venting element to disperse heat generated from the semiconductor assembly away from the device.

Of course, the consumer electronic device is provided with a power source to energize the semiconductor package(s).

The semiconductor package may be formed with a die attach material disposed between a semiconductor chip and a circuit board to securely adhere the chip to the board. Wire bonding forms the electrical interconnection between the chip and the board. This die attach material is oftentimes a highly filled material with a thermosetting resin matrix. The matrix may be composed of epoxy, maleimide, itaconimide, nadimide and/or (meth)acrylate. The filler may be conductive or non-conductive. In some instances, the die attach material is thermally conductive, in which case it too aids in dissipating heat away from the semiconductor package. Representative commercially available examples of such die attach materials include QMI519HT from Henkel Corporation, Irvine, Calif., US.

Alternatively, the semiconductor package may be formed with a semiconductor chip electrically connected to a circuit board with solder interconnects in a space therebetween. In that space an underfill sealant may be disposed. The underfill sealant will also have a thermosetting matrix resin, which like the die attach material may be composed of epoxy, maleimide, itaconimide, nadimide and/or (meth)acrylate. The underfill sealant is ordinarily also filled. However, the filler is generally non-conductive and used for the purpose of accommodating differences in the coefficients of thermal expansion of the semiconductor die and the circuit board. Representative commercially available examples of such underfill sealants include HYSOL FP4549HT from Henkel Corporation, Irvine, Calif., US.

Once the semiconductor package has been positioned onto the circuit board and attached thereto oftentimes by a surface mount adhesive, a chip bonder, or chip scale package underfill sealant, the package may be overmolded with mold compound in order to protect the package from among other things environmental contaminants. The mold compound is oftentimes epoxy based, but may also contain benzoxazine and/or other thermoset resins. GR750 is an example of an epoxy mold compound, available commercially from Henkel Corporation, Irvine, Calif., US, designed to improve thermal management in semiconductor devices.

Solder pastes are used at various portions on the circuit board to attach semiconductor packages and assemblies, in an electrically interconnected manner. One such solder paste is available commercially from Henkel Corporation, Irvine, Calif., US under the tradename MULTICORE Bi58LM100. This lead free solder paste is designed for applications where thermal management is desirable.

To effectively manage the heat generated by semiconductor chips and semiconductor packages, a thermal interface material may be used with any heat-generating component for which heat dissipation is required, and in particular, for heat-generating components in semiconductor devices. In such devices, the thermal interface material forms a layer between the heat-generating component and the heat sink and transfers the heat to be dissipated to the heat sink. The thermal interface material may also be used in a device containing a heat spreader. In such a device, a layer of thermal interface material is placed between the heat-generating component and the heat spreader, and a second layer of thermal interface material is placed between the heat spreader and the heat sink.

The thermal interface material may be a phase change material, such as one commercially available from Henkel Corporation, Irvine, Calif., US under the tradenames POWERSTRATE EXTREME, PowerstrateXtreme or PSX. Packaged as a free-standing film between two release liners and supplied as a die cut perform to match a wide variety of applications, this thermal interface material is a reworkable phase change material suitable for use for instance between a heat sink and variety heat dissipating components. The material flows at the phase change temperature, conforming to the surface features of the components. The thermal interface material when in the form of a phase change material has a melting point of approximately 51° C. or 60° C.

Upon flow, air is expelled from the interface, reducing thermal impedance, performing as a highly efficient thermal transfer material.

The thermal interface material may be constructed from (a) 60% to 90% by weight of paraffin; (b) 0% to 5% by weight of resin; and (c) 10% to 40% by weight of metal particle, such as an electrically-conductive filler. The electrically-conductive filler is ordinarily one selected from graphite, diamond, silver, and copper. Alternatively, the electrically-conductive filler may be aluminum, such as a spherical alumina.

The metal particles suitable for use in the thermal interface material may be fusible metal particles, typically low melting point metals or metal alloys used as solders. Examples of such metals include bismuth, tin, and indium, and may also include silver, zinc, copper, antimony, and silver coated boron nitride. In one embodiment the metal particles are selected from tin, bismuth, or both. In another embodiment, indium will also be present. Alloys of the above metals also can be used.

An eutectic alloy of tin and bismuth powder (melting point 138° C.), in a weight ratio of tin to bismuth of Sn48Bi52 may also be used, particularly in combination with indium powder (melting point 158° C.), in which the indium is present in a weight ratio of 1:1 with the Sn:Bi alloy.

The metal particles and/or alloys should be present in the composition in a range from 50 to 95 weight percent of the thermal interface material.

The thermal interface material may also be a thermal grease, such as one commercially available from Henkel Corporation, Irvine, Calif., US under the trade designations TG100, COT20232-3611 or COT20232-36E1. TG100 is a thermal grease designed for high-temperature heat transfer. In use, TG100 is placed between heat generating devices and the surfaces to which they are mounted or other heat dissipating surfaces. This product delivers excellent thermal resistance, offers high thermal conductivity and virtually no evaporation over a wide operating temperature range. In addition, COT20232-36E1 and COT20232-3611 are TIM1 type materials, designed in this instance for high power flip chip applications. These products contain a soft gel polymer or curable matrix, which after cure forms an interpenetrating network with a low melting point alloy therewithin. The low melting point alloy may be fusible metal solder particles, particularly those substantially devoid of added lead, comprising an elemental solder powder and optionally a solder alloy.

The thermal interface material in use should have a thermal impedance of less than 0.2 (° C. cm²/Watt).

The housing comprises at least two substrates and oftentimes a plurality of substrates. The substrates are dimensioned and disposed to engage one another. In order to manage the heat that may emanate from the interior of a consumer electronic device, and control the so called “skin temperature”, it is oftentimes desirable to place between the housing and the semiconductor devices that generate heat a thermal management solution.

Here, that solution is a composition comprising a matrix and a hydrated salt of a carboxylic or phosphoric acid and a Group I or II element of the Periodic Table.

The hydrated salt of an acid and a Group I or II element of the Periodic Table may have as the acid a carboxylic acid, a phosphoric acid, nitric acid, or sulfuric acid. As the carboxylic acid, a C₂₋₁₅ carboxylic acid-containing compound, such as aliphatic carboxylic acids like acetic, propionic, butanoic, pentanoic, hexanoic, heptanoic, and octanoic, and unsaturated carboxylic acids such as (meth)acrylic acid, and fatty acids are suitable.

The Group I element may be selected from lithium, sodium and potassium. Desirably, sodium is chosen.

The Group II element may be selected from magnesium and calcium.

Representative salts are shown below:

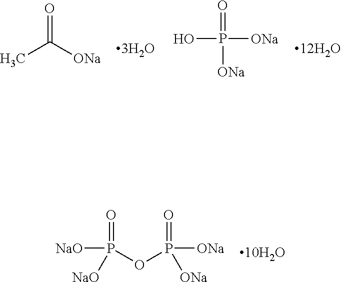

Examples of such hydrated salts based of an acid and a Group I or II element of the Periodic Table include sodium acetate trihydrate (melting point 58° C.), sodium pyrophosphate decahydrate (melting point 70° C.), and sodium sulphate decahydrate (melting point 33° C.), all of which are available commercially from Aldrich Chemical. Commercial PCM products based on salt hydrates include ClimSel C48 (sodium acetate; Phase Change Temperature: 48° C.; Latent Heat of Fusion: 68 Wh/Litre), ClimSel C58 (sodium acetate; Phase Change Temperature: 58° C.; Latent Heat of Fusion: 117 Wh/Litre), and ClimSel C70 (sodium pyrophosphate; Phase Change Temperature: 71° C.; Latent Heat of Fusion: 110 Wh/Litre), each available from Climator AB, Skovde, SWEDEN; and savENRG PCM 34P (Zn(NO3)2.6H20) and savENRG PCM 58P, each available from Rgees LLC, Candler, N.C.

In some embodiments, the hydrated salt of an acid and a Group I or II element of the Periodic Table may be present in the matrix in an encapsulated form. Examples of such encapsulated hydrated salts include THERMUSOL® HD60SAE MICRO ENCAPSULATED SALT-HYDRATES. See also U.S. Patent Application Publication No. US 2008/0255299.

The hydrated salt of an acid and a Group I or II element of the Periodic Table should be present in an amount of between about 15 percent by weight and about 65 percent by weight, such as about 25 percent by weight to about 50 percent by weight.

The matrix may be a PSA; an acrylic emulsion; or one or more of a (meth)acrylate, a maleimide-, an itaconimide- or a nadimide-containing compound. The PSA is ordinarily made from acrylic polymers, such as those having the following composition or those that can be prepared by polymerizing (i) an acrylic monomer which is an acrylic or methacrylic acid derivative (e.g. methacrylic acid ester) of the formula CH₂═CH(R¹)(COOR²), where R¹ is H or CH₃ and R² is a C₁₋₂₀, preferably C₁₋₈, alkyl chain and (ii) a monomer with a pendant reactive functional group, which is described in more detail herein below, and the amount of the monomer (ii) is from about 0.001 to about 0.015 equivalent per 100g of the acrylic polymer. See e.g. C. Houtman et al., “Properties of Water-based Acrylic Pressure Sensitive Adhesive Films in Aqueous Environments”, 2000TAPPI Recycling Symposium, Washington, D.C. (5-8 Mar. 2000).

For the polymerization process, the monomers of components (i) and (ii), where appropriate, are converted by radical polymerization into acrylic polymers. The monomers are chosen such that the resulting polymers can be used to prepare PSAs in accordance with D. Satas, “Handbook of Pressure Sensitive Adhesive Technology”, van Nostrand, N.Y. (1989).

Examples of acrylates and/or methacrylates useful as components of monomer mixture (i) include methyl acrylate, ethyl acrylate, ethyl methacrylate, methyl methacrylate, n-butyl acrylate, n-butyl methacrylate, n-pentyl acrylate, n-hexyl acrylate, n-heptyl acrylate, and n-octyl acrylate, n-nonyl acrylate, lauryl methacrylate, cyclohexyl acrylate, and branched (meth)acrylic isomers, such as i-butyl acrylate, i-butyl methacrylate, n-butyl methacrylate, 2-ethylhexyl acrylate, stearyl methacrylate, and isooctyl acrylate.

The exemplary acrylic monomer mixture (i) has a Tg value less than 0° C. and a weight average molecular weight from about 10,000 to about 2,000,000 g/mol, such as between 50,000 and 1,000,000 g/mol and desirably between 100,000 and 700,000 g/mol. The mixture (i) may be a single monomer provided that it has a homopolymer Tg of less than 0° C.

Examples of suitable monomer (ii) are those capable of providing green strength to the adhesive films, include cycloaliphatic epoxide monomers M100 and A400 (Daicel), oxetane monomer OXE-10 (available commercially from Kowa Company), dicyclopentadienyl methacrylate epoxide (CD535, available commercially from Sartomer Co., Exton, Pa.), and 4-vinyl-1-cyclohexene-1,2-epoxide (available commercially from Dow).

The acrylic polymers are capable of undergoing post-UV cationic activated reaction and thus, provide high temperature holding strength to the adhesive films. The acrylic polymers are those having the following composition or those that can be prepared by polymerizing (i) an acrylic monomer which is an acrylic or methacrylic acid derivative of the formula CH₂═CH(R₁)(COOR₂), where R₁ is H or CH₃ and R₂ is C₁₋₂₀ alkyl chain and (ii) a monomer with a combination of pendant reactive functional groups selected from both (1) cycloaliphatic epoxide, oxetane, benzophenone or mixtures thereof, and (2) mono-substituted oxirane. The amount of monomer (ii) is about 0.001 to about 0.015 equivalent per 100 g of the acrylic polymer. The acrylic polymer is essentially free of multi-(meth)acrylate, polyol or OH-functional groups and the polymer remains substantially linear after polymerization. In a more preferred embodiment, the amount of the monomer (ii) is from about 0.002 to about 0.01 equivalent per 100 g of the acrylic polymer.

The acrylic polymers prepared generally have a weight averaged average molecular weight (Mw) of from 10,000 to 2,000,000 g/mol, such as between 50,000 and 1,000,000 g/mol, like between 100,000 and 700,000 g/mol. M_{w} is determined by gel permeation chromatography or matrix-assisted laser desorption/ionization mass spectrometry.

Examples of mono-substituted oxiranes useful as monomer (ii) include glycidyl methacrylate, 1,2-epoxy-5-hexene, 4-hydroxybutylacrylate glycidyl ether, cycloaliphatic epoxide monomer M100 and A400, OXE-10, CD535 epoxide, and 4-vinyl-1-cyclohexene-1,2-epoxide.

The PSA may also comprise various other additives, such as plasticizers, tackifiers, and fillers, all of which are conventionally used in the preparation of PSAs. As plasticizers to be added, low molecular weight acrylic polymers, phthalates, benzoates, adipates, or plasticizer resins, are but a few possibilities. As tackifier or tackifying resins to be added, it is possible to use any known tackifying resins described in the literature. Non-limiting examples include pinene resins, indene resins, and their disproportionated, hydrogenated, polymerized, and esterified derivatives and salts, the aliphatic and aromatic hydrocarbon resins, terpene resins, terpene-phenolic resins, C₅ resins, C₉ resins, and other hydrocarbon resins. Any desired combinations of these or other resins may be used in order to adjust the properties of the resultant adhesive in accordance with the desired final properties.

The PSAs may further be blended with one or more additives such as aging inhibitors, antioxidants, light stabilizers, compounding agents, and/or accelerators.

Commercial representative examples of suitable PSAs include those available from Henkel Corporation, Irvine, Calif., US under the trade name DUROTAK.

Also as the matrix may be used a radically curable component, such as a (meth)acrylate and/or a maleimide-, an itaconimide- or a nadimide-containing compound.

The (meth)acrylate may be chosen from a variety of materials. Examples of such materials include (meth)acrylate functionalized polymers (where here the term polymer includes as well oligomers and elastomers), such as urethanes or polybutadienes. One particularly desirable example is a polybutadiene-dimethacrylate, a commercially available example of which is known as CN 303 from Sartomer Inc., Exton, Pa.

As a maleimide-, nadimide- or itaconimide-containing compound, compounds having the general respective structural formulae below may be used:

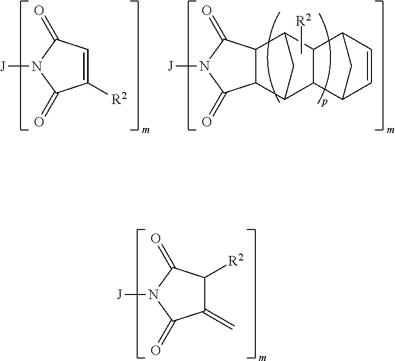

where here m is 1-15, p is 0-15, each R² is independently selected from hydrogen or lower alkyl (such as C₁₋₅), and J is a monovalent or a polyvalent radical comprising organic or organosiloxane radicals, and combinations of two or more thereof.

Monovalent or polyvalent radicals include hydrocarbyl or substituted hydrocarbyl species typically having a range of about 6 up to about 500 carbon atoms. The hydrocarbyl species may be alkyl, alkenyl, alkynyl, cycloalkyl, cycloalkenyl, aryl, alkylaryl, arylalkyl, aryalkenyl, alkenylaryl, arylalkynyl and alkynylaryl.

Additionally, X may be a hydrocarbylene or substituted hydrocarbylene species typically having in the range of about 6 up to about 500 carbon atoms. Examples of hydrocarbylene species include but are not limited to alkylene, alkenylene, alkynylene, cycloalkylene, cycloalkenylene, arylene, alkylarylene, arylalkylene, arylalkenylene, alkenylarylene, arylalkynylene and alkynylarylene.

The maleimide, itaconamide or nadimide may be in liquid or solid form.

In a desired embodiment, the maleimide, itaconamide or nadimide functional groups are separated by a polyvalent radical having sufficient length and branching to render the maleimide containing compound a liquid. The maleimide, itaconamide or nadimide compound may contain a spacer between maleimide functional groups comprising a branched chain alkylene between maleimide, itaconamide or nadimide functional groups.

In the case of maleimide-containing compounds, the maleimide compound desirably is a stearyl maleimide, oleyl maleimide, a biphenyl maleimide or a 1,20-bismaleimido-10,11-dioctyl-eixosane or combinations of the above.

Again in the case of maleimide-containing compounds, the maleimide compound may be prepared by reaction of maleic anhydride with dimer amides or prepared from aminopropyl-terminated polydimethyl siloxanes, polyoxypropylene amines, polytetramethyleneoxide-di-p-aminobenzoates, or combinations thereof.

Particularly desirable maleimides and nadimides include

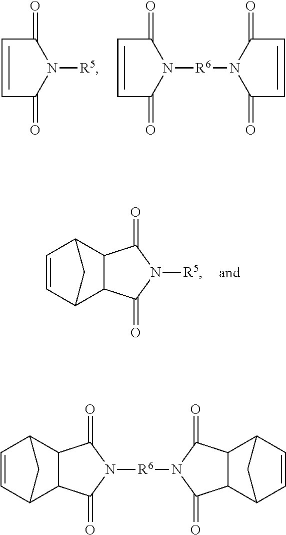

where here R⁵ and R⁶ are each selected from alkyl, aryl, aralkyl or alkaryl groups, having from about 6 to about 100 carbon atoms, with or without substitution or interruption by a member selected from silane, silicon, oxygen, halogen, carbonyl, hydroxyl, ester, carboxylic or phosphoricacid, urea, urethane, carbamate, sulfur, sulfonate and sulfone.

Other desirable maleimides, nadimides, and itaconimides include

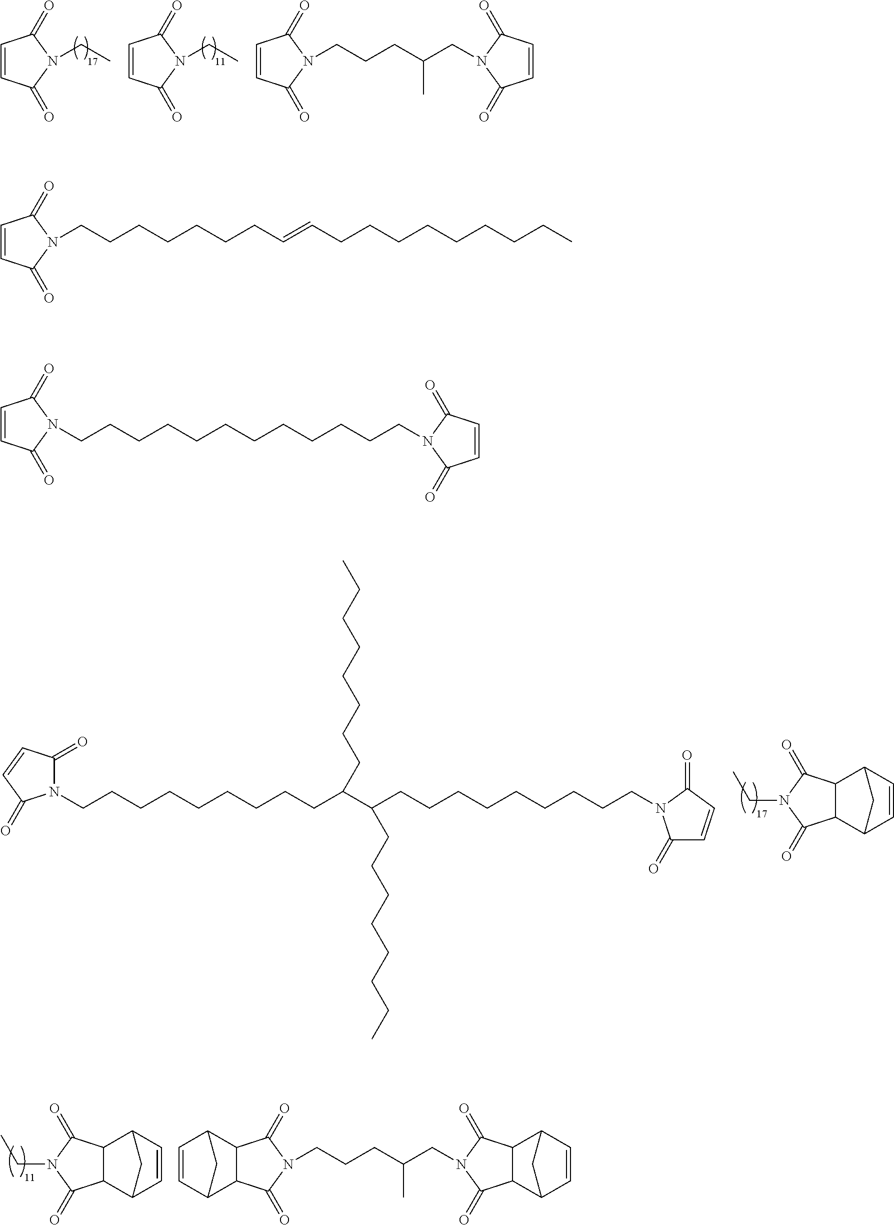

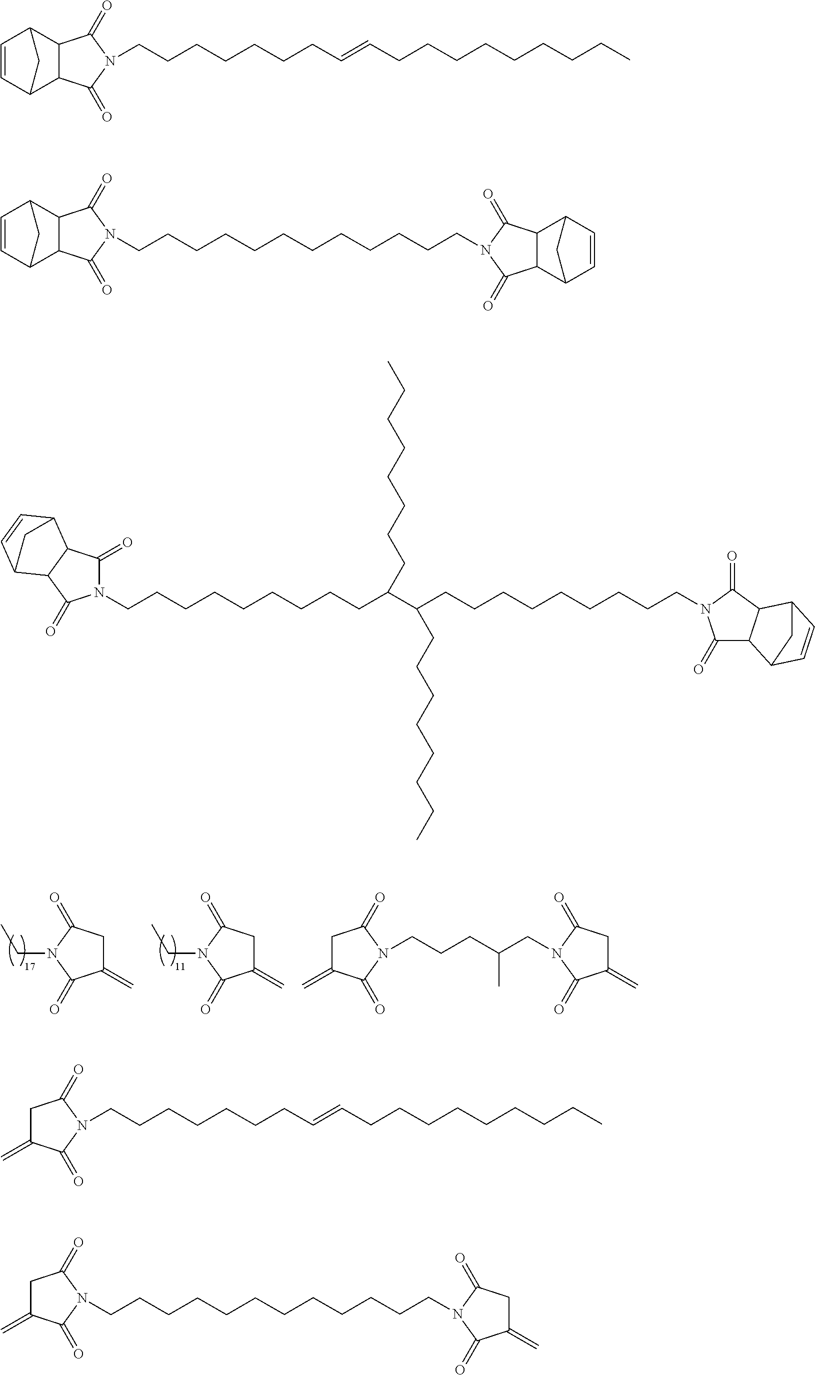

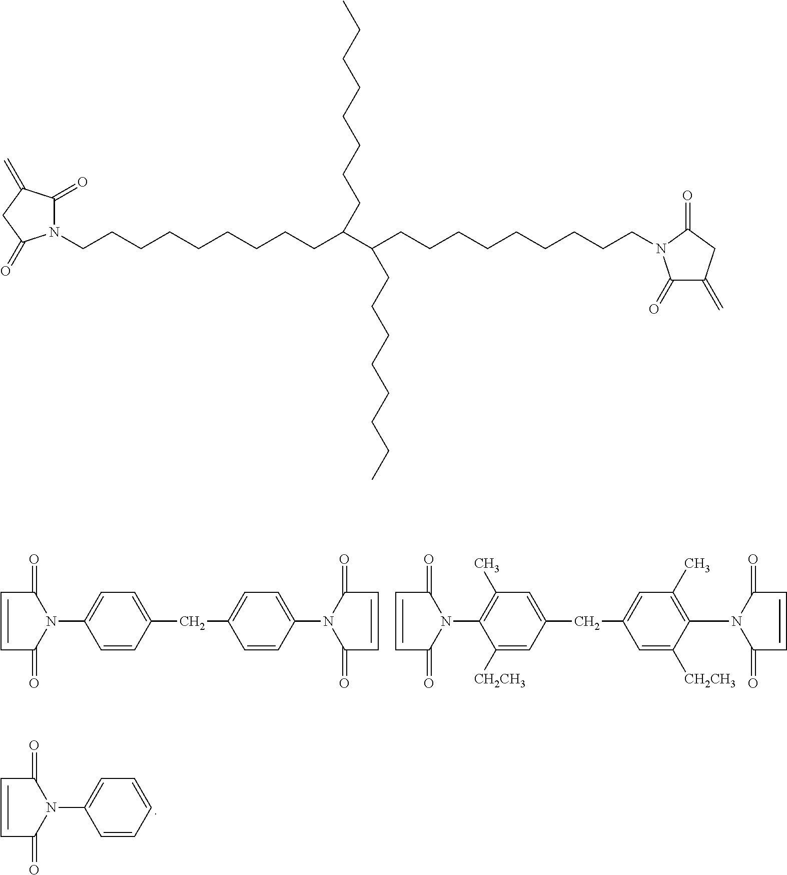

Optionally, thermal insulating elements or conductive particles may be included in the inventive compositions.

Representative commercially available examples of such thermal insulating elements include hollow sphere-like vessels, such as those sold under the DUALITE tradename by Henkel Corporation or the EXPANCEL tradename by Akzo Nobel, such as DUALITE E. DUALITE E is promoted to lower the thermal conductivity of the final product in which it is used as cost reducing or weight saving component. Using DUALITE E is reported to introduce stable, hollow, closed-cell voids into the final product.

In addition, solid materials having porosity or interstices in which gas is disposed may be used as an alternative to or in combination with the hollow sphere-like vessels. The thermally insulating elements in this regard may comprise a gas disposed within interstices of a substantially solid sphere-like particle. Representative commercially available examples of such thermally insulating elements include those sold under the AEROGEL NANOGEL tradename by Degussa Corporation. They are described by the manufacturer as lightweight, insulating silica materials, composed of a lattice network of glass strands with very small pores, composed from up to 5% solids and 95% air. This structure, it is reported, creates superior insulating, light transmitting and water repelling properties. The silica materials are a nanoporous silica with an average pore size of 20 nanometers. The small pore size and structure traps the flow of air to prevent heat loss and solar heat gain.

When used, the thermal insulating elements are disposed in a matrix at a concentration of 25% to 99% by volume in the matrix.

As noted, the inventive composition may also include thermally conductive particles. For example, such particles may be chosen from aluminum, aluminum oxide, aluminum silicon oxide and aluminum nitride.

When used, the thermally conductive particles are disposed in a matrix at a concentration of 25% to 99% by volume in the matrix.

The inventive composition may be disposed as a layer or coating on at least a portion of the surface of the substrate. The so-formed coating is thick enough to aid in creating a barrier to heat transmission through the substrate from the heat generated from the semiconductor packages when in use, but not so thick so as to interfere with the assembly and/or operation of the consumer electronic device.

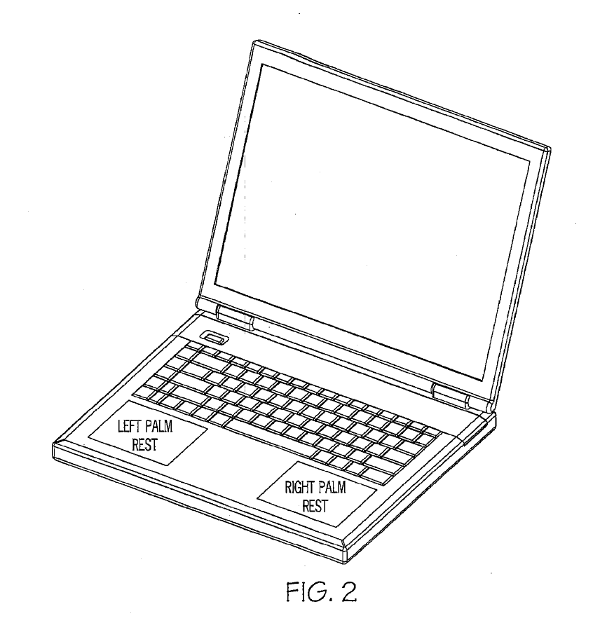

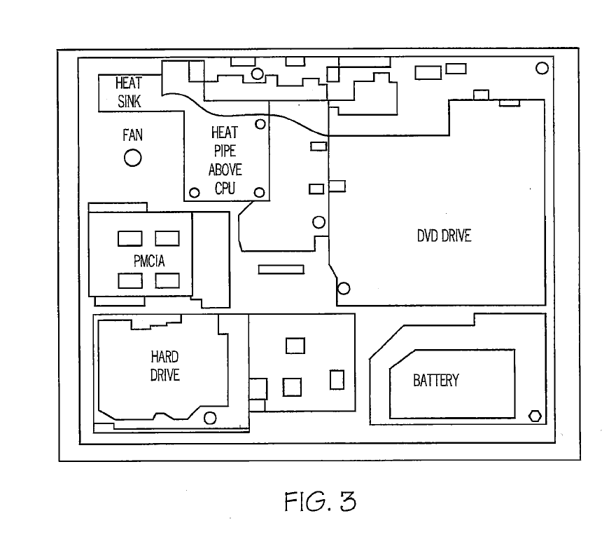

The inventive compositions should be disposed on at least a portion of the interior surface of the at least one substrate that comprises the housing, the complementary exterior surface of which comes into contact with the end user when in use. So, with reference to FIG. 2, palm rests would be good examples of this location on a lap top or notebook personal computer.

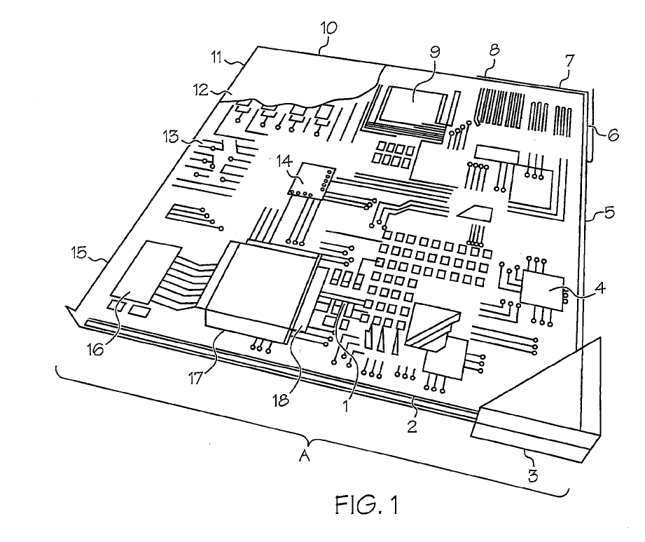

With reference to FIG. 1, a cut way view of a circuit board is shown. On the circuit board is disposed a plurality of semiconductor packages and circuitry, together with electronic materials ordinarily used in the assembly of the packages themselves and the assembly of the packages onto the board, and a portion of the housing of the electronic device in which the circuit board is to be used. In FIG. 1, 1 refers to surface mount adhesives (such as LOCTITE 3609 and 3619); 2 refers to thermal interface materials, as described in more detail herein; 3 refers to low pressure molding materials (such as MM6208); 4 refers to flip chip on board underfill such as HYSOL FP4531); 5 refers to liquid encapsulants glob top (such as HYSOL E01016 and E01072); 6 refers to silicone encapsulants (such as LOCTITE 5210); 7 refers to gasketing compounds (such as LOCTITE 5089); 8 refers to a chip scale package/ball grid array underfill (such as HYSOL UF3808 and E1216); 9 refers to a flip chip air package underfill (such as HYSOL FP4549 HT); 10 refers to coating powder (such as HYSOL DK7-0953M); 11 refers to mechanic molding compound (such as HYSOL LL-1000-3NP and GR2310); 12 refers to potting compound (such as E&C 2850FT); 13 refers to optoelectronic (such as Ablestik AA50T); 14 refers to die attach (such as Ablestick 0084-1LM1SR4, 8290 and HYSOL OMI529HT); 15 refers to conformal coating (such as LOCTITE 5293 and PC40-UMF); 16 refers to photonic component and assembly materials (such as STYLAST 2017M4 and HYSOL OT0149-3); 17 refers to semiconductor mold compound ; and 18 refers to solder (such as Multicore BI58LM100AAS90V and 97SCLF318AGS88.5). Each of these products is available for sale commercially from Henkel Corporation, Irvine, Calif.

The circuit board A of FIG. 1 is disposed within the interior of the housing of an electronic device (not shown). On at least a portion of an inwardly facing surface of a substrate which comprises the housing of the electronic device is coated a layer of thermally insulating elements (not shown).

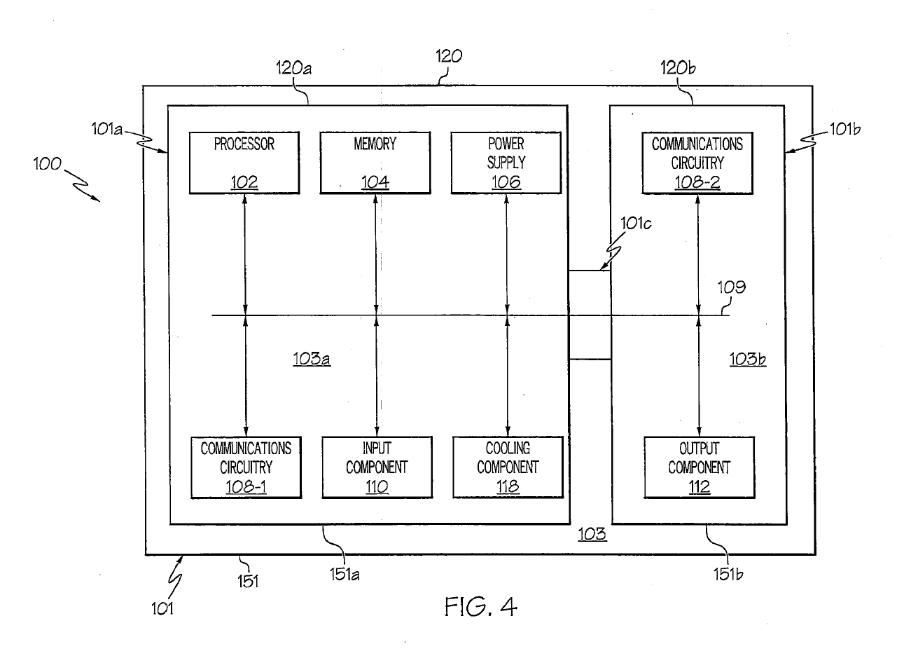

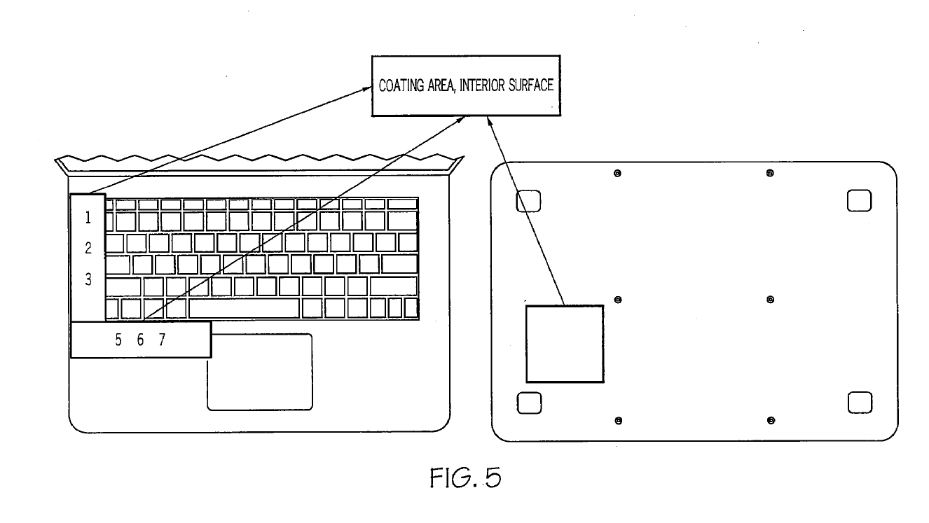

As shown in FIG. 4, electronic device 100 may include housing 101, processor 102, memory 104, power supply 106, communications circuitry 108-1, bus 109, input component 110, output component 112, and cooling component 118. Bus 109 may include one or more wired or wireless links that provide paths for transmitting data and/or power, to, from, or between various components of electronic device 100 including, for example, processor 102, memory 104, power supply 106, communications circuitry 108-1, input component 110, output component 112, and cooling component 118.

Memory 104 may include one or more storage mediums, including, but not limited to, a hard-drive, flash memory, permanent memory such as read-only memory (“ROM”), semi-permanent memory such as random access memory (“RAM”), any other suitable type of storage component, and any combinations thereof. Memory 104 may include cache memory, which may be one or more different types of memory used for temporarily storing data for electronic device applications.

Power supply 106 may provide power to the electronic components of electronic device 100, either by one or more batteries or from a natural source, such as solar power using solar cells.

One or more input components 110 may be provided to permit a user to interact or interface with device 100, such as by way of an electronic device pad, dial, click wheel, scroll wheel, touch screen, one or more buttons (e.g., a keyboard), mouse, joy stick, track ball, microphone, camera, video recorder, and any combinations thereof.

One or more output components 112 can be provided to present information (e.g., textual, graphical, audible, and/or tactile information) to a user of device 100, such as by way of audio speakers, headphones, signal line-outs, visual displays, antennas, infrared ports, rumblers, vibrators, and any combinations thereof.

One or more cooling components 118 can be provided to help dissipate heat generated by the various electronic components of electronic device 100. These cooling components 118 may take various forms, such as fans, heat sinks, heat spreaders, heat pipes, vents or openings in housing 101 of electronic device 100, and any combinations thereof.

Processor 102 of device 100 may control the operation of many functions and other circuitry provided by device 100. For example, processor 102 can receive input signals from input component 110 and/or drive output signals through output component 112.

Housing 101 should provide at least a partial enclosure to one or more of the various electronic components that operate electronic device 100. Housing 100 protects the electronic components from debris and other degrading forces external to device 100. Housing 101 may include one or more walls 120 that define a cavity 103 within which various electronic components of device 100 can be disposed. Housing openings 151 may also allow certain fluids (e.g., air) to be drawn into and discharged from cavity 103 of electronic device 100 for helping to manage the internal temperature of device 100. Housing 101 can be constructed from a variety of materials, such as metals (e.g., steel, copper, titanium, aluminum, and various metal alloys), ceramics, plastics, and any combinations thereof.

Rather than being provided as a single enclosure, housing 101 may also be provided as two or more housing components. Processor 102, memory 104, power supply 106, communications circuitry 108-1, input component 110, and cooling component 118 may be at least partially contained within a first housing component 101a, for instance, while output component 112 may be at least partially contained within a second housing component 101b.

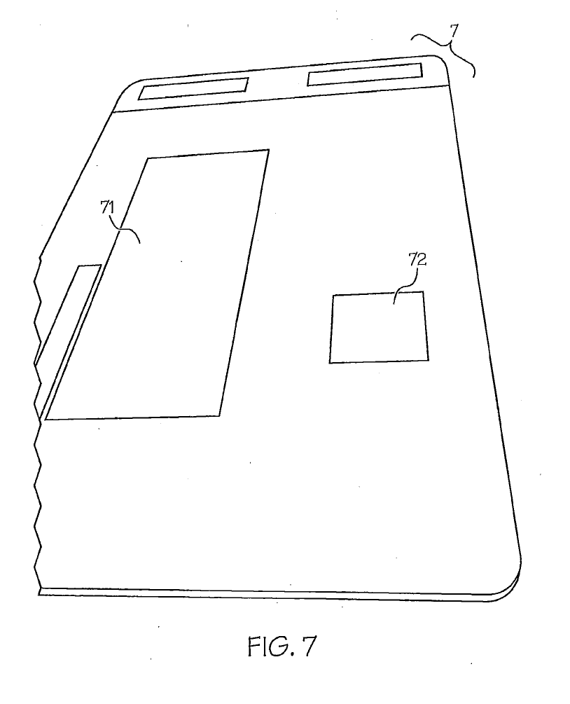

With respect to a power module assembly, the composition may be disposed on a surface of a power module. For instance, a power module assembly is provided, which comprises a power module having at least two surfaces, and a composition comprising a plurality of encapsulated phase change material particles dispersed within a matrix disposed upon at least a portion of one of the surfaces. Reference to FIG. 7 shows such a power module 71 within the interior of a tablet 7 and a CPU 72 in proximity thereto.

### EXAMPLES

For Sample No. 1, the following constituents in the noted weight percentages were mixed together: telechelic polyacrylate (commercially available from Kaneka Corporation under the tradename RC100C): 19.5%; mono-functional telechelic acrylate (commercially available from Kaneka Corporation under the tradename MM110C): 39.9%; sodium acetate trihydrate (CH3O2Na·3H2O): 40%; and TRIGONOX 141:0.6%.

Sample No. 1 was placed in an oven at a temperature of 70° C. for a period of time of 16 hours, after which a reaction product was observed as a creamy, high consistency paste. A DSC of the sample revealed a latent heat value of 207 J/g and a melting point of 63° C. The latent heat value was stable with additional heat cycle applied.

For Sample No. 2, the following constituents in the noted weight percentages were mixed together: telechelic polyacrylate (commercially available from Kaneka Corporation under the tradename RC100C): 19.4%; behenyl acrylated wax: 40%; sodium acetate trihydrate (CH3O2Na·3H2O): 40%; and TRIGONOX 141:0.6%.

Sample No. 2 was placed in an oven at a temperature of 70° C. for a period of time of 16 hours, after which a reaction product was observed as a solid wax. A DSC of the sample revealed a latent heat value of 430 J/g and a melting point of 67° C. The latent heat value was stable with additional heat cycle applied.

For Sample No. 3, the following constituents in the noted weight percentages were mixed together: myristic acid (PT58): 64%; sodium acetate trihydrate (CH3O2Na·3H2O): 32%; and ethylene butylene copolymer (DYNARON 6360B): 4%.

Sample No. 3 was placed in an oven at a temperature of 70° C. for a period of time of 16 hours, after which a reaction product was observed as a solid wax. A DSC of the sample revealed a latent heat value of 319 J/g and a melting point of 60° C. The latent heat value decreased to about 200 J/g with additional heat cycle applied.

Sample No. 4 is presented as a control. Here, sodium acetate trihydrate (CH3O2Na·3H2O): 100% was used.

Sample No. 4 was placed in an oven at a temperature of 70° C. for a period of time of 16 hours, after which a reaction product was observed as a solid wax. A DSC of the sample revealed a latent heat value of 290 J/g and a melting point of 58° C. No re-melting was observed in the subsequent heat cycles due to phase separation of water and the Na salt. The latent heat value decreased to about 200 J/g with additional heat cycle applied.

Sample No. 5 is also presented as a control. Here, sodium pyrophosphate decahydrate (Na4O7P2.10H2O): 100% was used.

Sample No. 5 was placed in an oven at a temperature of 70° C. for a period of time of 16 hours, after which a reaction product was observed as a solid wax. A DSC of the sample revealed a latent heat value of 1440 J/g and a melting point of 71.7° C. No re-melting was observed in the subsequent heat cycles due to phase separation of water and the Na salt. The latent heat value decreased to about 200 J/g with additional heat cycle applied.

Sample No. 6 is presented as another control using the following constituents: myristic acid (96% by weight) and DYNARON 6360B (4% by weight). A DSC of the sample showed a latent heat value of 210 J/g and a melting point of 58° C. The latent heat value is significantly lower than that of Sample No. 3, which also had the hydrated salt.

For Sample No. 7, the following constituents in the noted weight percentages were mixed together: sodium acetate trihydrate: 92%, sodium pyrophosphate decahydrate: 2%, fumed silica: 2%, and water: 4%.

Sample No.7 was placed in an oven at 70° C. for a period of time of 16 hours, after which a reaction product was observed as a solid material. A DSC of the sample showed a latent heat value of 400 J/g and a melting point of 60° C.

What is claimed is:

1. A composition comprising:
(a) a matrix; and
(b) a hydrated salt of an acid and a Group I or II element of the Periodic Table.

2. The composition of claim 1, wherein the matrix is a radically curable composition.

3. The composition of claim 1, wherein the matrix is selected from a (meth)acrylate, a maleimide-, an itaconimide- or a nadimide-containing compound.

4. The composition of claim 1, wherein the acid is selected from a carboxylic acid, a phosphoric acid, nitric acid or sulfuric acid.

5. The composition of claim 4, wherein the acid is a carboxylic acid.

6. The composition of claim 5, wherein the carboxylic acid is a C₂₋₁₅ carboxylic acid-containing compound.

7. The composition of claim 5, wherein the carboxylic acid is selected from acetic acid, propionic acid, butanoic acid, pentanoic acid, hexanoic acid, heptanoic acid, octanoic acid, (meth)acrylic acid, and fatty acids.

8. The composition of claim 1, wherein the Group I element is selected from lithium, sodium and potassium.

9. The composition of claim 1, wherein the Group II element is selected from magnesium and calcium.

10. The composition of claim 1, wherein the hydrated salt of an acid and a Group I or II element of the Periodic Table is encapsulated.

11. The composition of claim 1, wherein the hydrated salt (b) is present in an amount of between about 15 percent by weight and about 65 percent by weight.

12. A consumer electronic article of manufacture comprising:
A housing comprising at least one substrate having an interior surface and an exterior surface;
A composition of claim 1, disposed on at least a portion of the interior surface of the at least one substrate; and
At least one semiconductor package comprising an assembly comprising at least one of
I.
a semiconductor chip;
a heat spreader; and
a thermal interface material therebetween, or
II.
a heat spreader;
a heat sink; and
a thermal interface material therebetween.

13. The article of manufacture of claim 12, further comprising a venting element to disperse generated heat from the semiconductor assembly from the article.

14. The article of manufacture of claim 12, wherein the housing comprises at least two substrates.

15. The article of manufacture of claim 12, wherein the housing comprises a plurality of substrates.

16. The article of manufacture of claim 12, wherein the substrates are dimensioned and disposed to engage one another.

17. The article of manufacture of claim 12, wherein composition is disposed on at least a portion of the interior surface of the at least one substrate, the complementary exterior surface of which comes into contact with the end user when in use.

18. The article of manufacture of claim 12, further comprising thermally insulating elements.

19. The article of manufacture of claim 18, wherein the thermally insulating elements in the composition comprise a gas.

20. The article of manufacture of claim 18, wherein the thermally insulating elements in the composition comprise air.

21. The article of manufacture of claim 18, wherein the thermally insulating elements in the composition comprise a gas within a hollow sphere-like vessel.

22. The article of manufacture of claim 18, wherein the thermally insulating elements are used at a concentration within the range of 25% to 99% by volume in the composition.

23. The article of manufacture of claim 12, further comprising thermally conductive particles.

24. The article of manufacture of claim 23, wherein the thermally conductive particles are one or more of aluminum, aluminum oxide, aluminum silicon or aluminum nitride.

25. The article of manufacture of claim 12, wherein the composition facilitates the transfer of heat from an electronic component to a heat sink.

26. The article of manufacture of claim 12, wherein the thermal interface material has a melting point of approximately 37° C.

27. The article of manufacture of claim 12, the thermal interface material material has a melting point of approximately 52° C.

28. The article of manufacture of claim 12, the article is a notebook personal computer, tablet personal computer or a handheld device.

29. The composition of claim 1, disposed on a metallic, metal-coated polymeric, graphite or metal-coated graphitic substrate.

30. A power module assembly comprising:
A power module having at least two surfaces, and
A composition of claim 1 disposed upon at least a portion of one of the surfaces.
